(19) United States
(12) Patent Application Publication
(10) Pub. No.: US 2026/0353669 A1
(43) Pub. Date: Nov. 5, 2026

(54) SKYRMION TRANSISTOR

(71) Applicant: KOREA RESEARCH INSTITUTE OF STANDARDS AND SCIENCE, Daejeon (KR)

(72) Inventors: Chan Yong HWANG, Seoul (KR); Kyoung Woong MOON, Daejeon (KR); Seung Mo YANG, Daejeon (KR)

(21) Appl. No.: 19/486,158

(22) PCT Filed: Nov. 6, 2023
(86) PCT No.: PCT/KR2023/017624

§ 371 Date: Nov. 20, 2025

(30) Foreign Application Priority Data
Jun. 2, 2023 (KR) 10-2023-0071779

(51) Int. Cl. H10B 61/00

(52) U.S. Cl. CPC H10B 61/22

(57) ABSTRACT

Provided is a skyrmion transistor including: a substrate; a skyrmion channel formed on the substrate, and composed of a first thin film stack which includes a magnesium oxide (MgO) layer, a cobalt iron boron (CoFeB) layer and a heavy metal layer and of which one side is grounded; and a skyrmion generator and a skyrmion gate, which are composed of the first thin film stack and a second thin film stack formed in a predetermined upper area thereof and composed of an aluminum oxide (AlOₓ) layer and an electrode layer. The skyrmion gate of the present invention can pass or block skyrmion by controlling a gate voltage.

### TECHNICAL FIELD

The present invention relates to a skyrmion transistor, and more particularly, to a skyrmion transistor using a gate voltage.

### BACKGROUND ART

Although traditional microelectronic devices perform charge transfer operation based on electrons, spin electronic devices perform storage, transmission, and processing of information on the basis of spin properties of electrons.

The field that develops electronic devices, such as next-generation memory, using spin is referred to as spintronics. Existing semiconductor-based electronic device techniques control only charges using electric fields, without considering quantum-mechanical spin, among two properties of electrons, i.e., charge and spin. The spintronics technique is a technique that simultaneously controls both the charge and spin and is expected to overcome technical limitations of existing electronic devices. As spin electronic devices have unique properties of spin, such as non-volatility, as well as ultra-high speed, ultra-low power, ultra-high frequency, and the like, they will be used as a next-generation electronic device.

Recently, researches for developing next-generation electronic devices, such as memory, logic devices, communication devices, and the like, using magnetic skyrmions (spin structure formed as spins are arranged in a vortex shape) as shown in FIG. 1 are conducted actively.

In order to utilize skyrmions in electronic devices, each skyrmion, which is the basic unit of information storage (bit), should be able to be generated and deleted at a desired position, and the generated skyrmions should be able to be shifted with very high efficiency.

Although several studies suggest the possibility of realizing skyrmion apparatuses using voltage-controlled skyrmion manipulation (S. Luo, M. Song, X. Li, Y. Zhang, J. Hong, X. Yang, X. Zou, N. Xu, L. You, Nano Lett. 2018, 18), it has not yet been experimentally proved. The reason is that as most voltage-controlled skyrmion manipulations are dominated by defects or oxygen ion migration, slow or spatially non-uniform operations are shown.

Particularly, in the case of skyrmion logic devices, as skyrmions should frequently move across controlled and non-controlled regions while maintaining topological information, an interface where different regions of magnetic anisotropy are continuously well connected is essential. However, such a technique is not yet provided. Existing voltage-controlled magnetic anisotropy (VCMA) techniques control magnetic properties by bonding a magnetic thin film and an insulator containing oxygen and applying voltage. This is a mechanism in which electric fields control magnetic anisotropy by changing the oxidation state of the interface between an oxide layer and a magnetic layer through oxygen ion migration.

However, such a conventional voltage-controlled magnetic anisotropy technique shows a slow and non-uniform operation as the magnetic anisotropy is spatially non-uniform due to oxygen migration or defects.

Recent studies (A J Tan, M Huang, C O Avci, F Buttner, Mann, W Hu, C Mazzoli, S. Wilkins, H. L. Tuller, G. S. D. Beach, Nat. Mater. 2019, 18, 35) has reported voltage-controlled magnetic anisotropy using protons instead of oxygen, which shows relatively fast and stable operation. However, these studies do not show spatial uniformity of magnetic anisotropy.

### DISCLOSURE OF INVENTION

### Technical Problem

Therefore, the present invention has been made in view of the above problems, and an object of the present invention is to provide a fast and stable skyrmion transistor using a voltage-controlled magnetic anisotropy technique that shows spatially uniform magnetic anisotropy.

### Technical Solution

To accomplish the above object, according to one aspect of the present invention, there is provided a skyrmion transistor comprising: a substrate; a skyrmion channel configured of a first thin film stack formed on the substrate to include a magnesium oxide (MgO) layer, a cobalt iron boron (CoFeB) layer, and a heavy metal layer, one side of which is grounded; and a skyrmion generator and a skyrmion gate configured of the first thin film stack and a second thin film stack formed in a predetermined upper region thereof to include an aluminum oxide (AlOₓ) layer and an electrode layer.

In addition, in the present invention, the skyrmion gate may pass or block skyrmions by adjusting a gate voltage.

In addition, in the present invention, a perpendicular magnetic anisotropy of the gated region is adjusted by applying the gate voltage to control an energy barrier through which the skyrmions may pass, and there is a threshold value of the perpendicular magnetic anisotropy of the gated region, at which the skyrmion transistor may operate, and the skyrmion transistor may operate at the threshold value or higher.

In addition, in the present invention, the skyrmion gate may pass or block skyrmions by adjusting in-plane current.

In addition, in the present invention, the skyrmion generator controls the perpendicular magnetic anisotropy of a skyrmion generator region by applying a voltage to the skyrmion generator region through the electrode layer, and forms a skyrmion generating state in the skyrmion generator region and a skyrmion stable state in a skyrmion channel region by adjusting perpendicular magnetic fields of the skyrmion generator region and the skyrmion channel region, and discharges skyrmions from the skyrmion generator region to the skyrmion channel region by applying an in-plane current.

In addition, in the present invention, when a voltage is applied to a gated region, perpendicular magnetic anisotropy appears spatially uniform in the gated region.

In addition, in the present invention, the aluminum oxide layer is formed by atomic layer deposition (ALD) using an aluminum precursor and water at a relatively low temperature within a temperature range capable of deposition, and the aluminum oxide layer contains hydrogen.

In addition, in the present invention, the heavy metal layer is preferably configured of at least one among W, Ta, Nb, and Hf, and an ultra-thin metal layer may be interposed between the cobalt iron boron layer and the magnesium oxide layer, and a natural oxide layer or a metal oxide layer may be formed on the top of the heavy metal layer.

In addition, in the present invention, a magnetic image observed in the gated region using a Magneto-optical Kerr effect (MOKE) microscope shows a uniform stripe domain width.

In addition, in the present invention, at an interface between the gated region and the non-gated region having different perpendicular magnetic anisotropy, magnetization domains are spatially and continuously connected, and domain wall chirality is well conserved.

In addition, in the present invention, an in-plane current is a pulse current, and the number of generated skyrmions may be adjusted by controlling an amplitude and time thereof.

### Advantageous Effects

The present invention may propose a voltage-controlled skyrmion stabilization technique accomplished by manipulating the PMA and stripe domain width. As the shape and topology of the skyrmions are well conserved as the skyrmions pass through the interface between the controlled and non-controlled regions, spatial uniformity of the voltage-controlled region may be appropriately applied to the skyrmion transistor of the present invention.

In addition, a new skyrmion generator having the concept of skyrmion reservoir may be provided using the voltage-controlled skyrmion stabilization technique presented in the present invention, and a new non-volatile skyrmion transistor may be provided by combining the concept of skyrmion generator with a precise voltage-controlled PMA.

### BRIEF DESCRIPTION OF THE DRAWINGS

FIG. 1 is a view showing the configuration of a conventional voltage-controlled magnetic anisotropy (VCMA) experiment.

FIG. 2 is a view showing the concept of skyrmion.

FIG. 3 is a view showing the structure of a thin film stack according to an embodiment of the present invention.

FIG. 4 is a view showing setup of a MOKE microscope experiment.

FIG. 5 is a view showing the planar structure and pattern of a thin film stack according to an embodiment of the present invention.

FIGS. 6A-6C are views showing changes in the stripe domain width occurred by applying a positive voltage pulse to the gated region.

FIGS. 7A-7F are views showing fast Fourier transform images of a gated region and a non-gated region.

FIG. 8(a) is a view showing the relationship between the gate voltage pulse and the perpendicular magnetic anisotropy field, and FIG. 8(b) is a view showing X-ray photoelectron spectroscopy analysis of the non-gate (solid line) and gate (dashed line) regions using in situ etching.

FIG. 9 is a view showing movement of the gated region due to strong transverse current injection.

FIG. 10 is a view showing the results of investigating spatial uniformity of voltage-controlled perpendicular magnetic anisotropy.

FIG. 11 is a view showing the results of investigating magnetic domain connection between a gated region and a non-gated region.

FIG. 12 is a view showing MOKE images of a stripe domain at various μ₀H_{Z}.

FIG. 13 is a view showing the phase diagram between the voltage-controlled stripe domain width and the stripe domain-skyrmion-uniform state under the z-axis magnetic field.

FIG. 14(a) is a view showing mapping of an effective perpendicular magnetic anisotropy field, and FIGS. 14(b) and (c) show MOKE images in the initial state and after injection of in-plane current, respectively.

FIG. 15(a) is a view showing a skyrmion transistor according to an embodiment of the present invention, and FIGS. 15(b) to (p) are views showing the operation of the skyrmion transistor according to an embodiment of the present invention.

FIG. 16 is a view showing the number of skyrmions generated by a skyrmion generator according to the amplitude and time of injected current pulse.

FIG. 17 is a view showing a micromagnetic simulation of a skyrmion transistor.

FIG. 18 is a view showing various operations of a skyrmion transistor.

FIG. 19 is a view showing the threshold current of a skyrmion for overcoming the energy barrier of a gate as a function of Hₖ difference between a channel region and a gated region.

FIG. 20 is a view showing that a skyrmion transistor does not operate when the PMA of the gated region is smaller than the threshold value.

FIG. 21 is a graph showing VCMA efficiency with respect to the electric field.

FIG. 22 is a graph showing energy consumption for VCMA operation.

FIG. 23 is a graph showing total energy dissipation with respect to the length of a gate.

### BEST MODE FOR CARRYING OUT THE INVENTION

Hereinafter, preferred embodiments of the present invention will be described in detail with reference to the accompanying drawings. However, the present invention is not limited to the embodiments described herein and may be embodied in other forms. Rather, the embodiments introduced herein are provided to ensure that the disclosure is thorough and complete and to sufficiently convey the spirit of the present invention to those skilled in the art.

The skyrmion transistor of the present invention is configured to include a skyrmion channel, and a skyrmion generator and a skyrmion gate formed in a predetermined region on the skyrmion channel, and may pass or block skyrmions by adjusting the gate voltage.

The skyrmion channel is configured of a first thin film stack formed on a substrate to include a magnesium oxide (MgO) layer, a cobalt iron boron (CoFeB) layer, and a heavy metal layer, one side of which is grounded.

The skyrmion generator and skyrmion gate are configured of the first thin film stack and a second thin film stack formed in a predetermined upper region thereof to include an aluminum oxide (AlOₓ) layer and an electrode layer.

The skyrmion generator may control the perpendicular magnetic anisotropy of a corresponding region by applying a voltage to the skyrmion generator region through the electrode layer, and form a skyrmion generating state in the skyrmion generator region and a skyrmion stable state in the skyrmion channel region by adjusting the perpendicular magnetic fields of the skyrmion generator region and the skyrmion channel region, and may discharge skyrmions from the skyrmion generator region to the skyrmion channel region by applying an in-plane current.

In addition, in the present invention, the heavy metal layer is preferably configured of at least one among W, Ta, Nb, and Hf, and an ultra-thin metal layer may be interposed between the cobalt iron boron layer and the magnesium oxide layer, and a natural oxide layer or a metal oxide layer may be formed on the top of the heavy metal layer.

Hereinafter, a skyrmion transistor according to an embodiment of the present invention will be described with reference to the drawings.

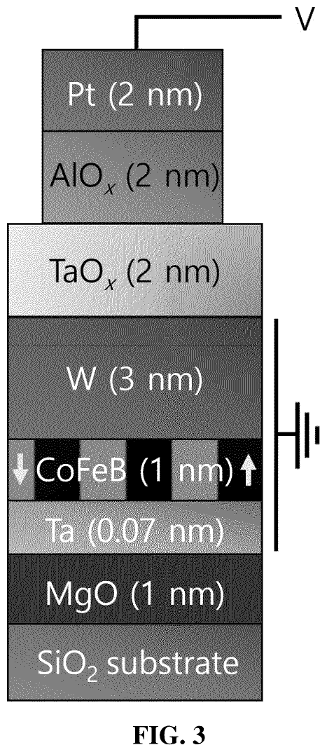

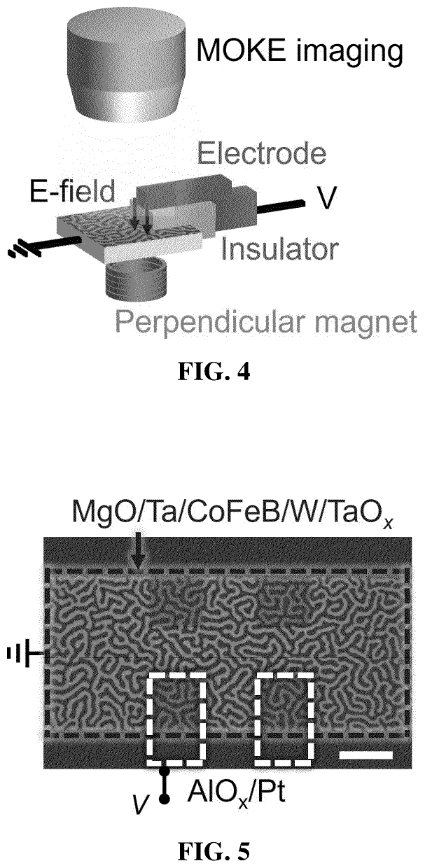

FIG. 3 is a view showing the structure of a thin film stack applied to a skyrmion transistor according to an embodiment of the present invention, and FIG. 4 is a view showing setup of a MOKE microscope experiment.

FIG. 5 is a view showing the planar structure and pattern of a thin film stack according to an embodiment of the present invention. The thin film stack of MgO/Ta/CoFeB/W/TaOₓ is patterned in a wire shape indicated by the black dashed line, and the AlOₓ(2 nm)/Pt(2 nm) thin film stack grows in the area of the white dashed line. The dark gray and light gray colors of the pattern correspond to −z and +z magnetization, respectively (Scale bar: 30 μm).

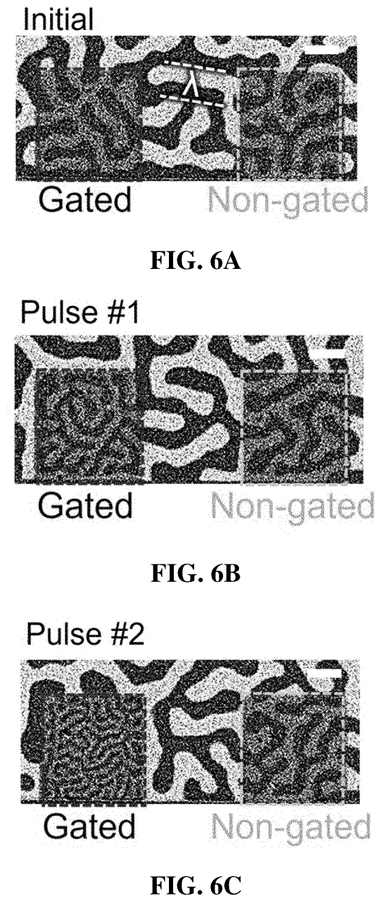

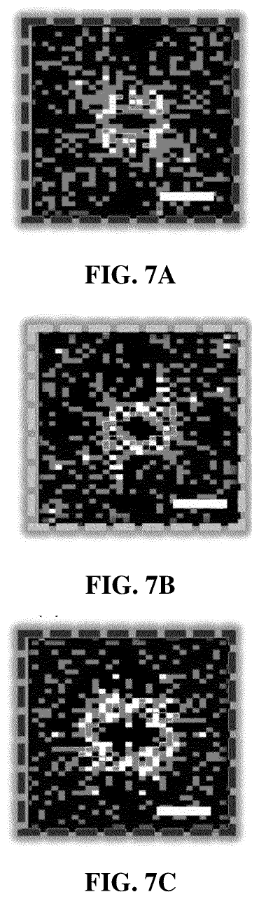

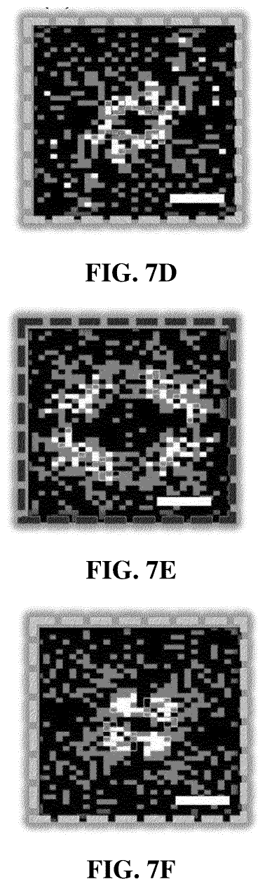

FIGS. 6A-6C are views showing changes in the stripe domain width occurred by applying a positive voltage pulse to the gated region (Scale bar: 10 μm), and FIGS. 7A-7F are views showing fast Fourier transform images of a gated region and a non-gated region (Scale bar: 0.1 μm⁻¹).

The basic structure of the skyrmion transistor according to an embodiment of the present invention is as shown in FIG. 3. The thin film stack of the skyrmion forming apparatus of the present invention is formed to include a substrate, a first thin film stack configured of MgO(1.0 nm)/Ta(0.07 nm)/Co₂₀Fe₆₀B₂₀(1.0 nm)/W(3.0 nm)/TaOₓ(2 nm), and a second thin film stack configured of AlOₓ(2 nm)/Pt(2 nm).

In the present invention, the first thin film stack may be configured of only a magnesium oxide (MgO) layer, a cobalt iron boron (CoFeB) layer, and a heavy metal layer, and at least one among W, Ta, Nb, and Hf may be used as the heavy metal layer. The metal oxide layer as shown in FIG. 3 may be formed on the heavy metal layer, or may be formed as a natural oxide layer.

An ultra-thin metal layer may be interposed between the CoFeB layer and the MgO layer to more precisely control the perpendicular magnetic anisotropy (PMA) by adjusting the PMA appearing at the interface.

In an embodiment of the present invention, a stack of MgO(1 nm)/Ta(0.07 nm)/Co₂₀Fe₆₀B₂₀(1.0 nm)/W(3 nm)/TaOₓ(2 nm) is deposited on a thermally oxidized Si substrate using a magnetron sputtering system of a base pressure of 4.0 torr at room temperature, and PMA is promoted by performing a post-annealing process at 350 °C for 1 hour under the vacuum condition of 5.0 or less.

An ultra-thin (0.07 nm) Ta layer is inserted to precisely control the PMA that occurs at the CoFeB/MgO interface. Since the PMA occurring at the CoFeB/MgO interface should be small to form the skyrmion, the PMA occurring at the CoFeB/MgO interface is lowered by inserting the very thin Ta layer of about one atomic layer to control the PMA more precisely.

The first thin film stack of MgO/Ta/CoFeB/W/TaOₓ is patterned in a wire shape using photolithography and ion milling (the black dashed line area shown in FIG. 5). Then, the AlOₓ(2 nm)/Pt(2 nm) layer is deposited on the gated region (the white dashed line area shown in FIG. 5) on top of the first thin film stack.

Here, the AlOₓ layer is deposited using a thermal atomic layer deposition (ALD) system at 120 °C. Tri-methyl-aluminum (TMA) and water (H₂O) are used as precursors, and nitrogen gas (N₂) is used as a carrier and purging gas.

In the present invention, as the AlOₓ layer is formed at a relatively low temperature of 120 °C within the temperature range where deposition is possible, hydrogen is not evaporated in the deposition process and remains inside the AlOₓ layer. That is, in the present invention, the AlOₓ layer contains hydrogen, and when an electric field is applied through the Pt layer, which is an electrode layer, hydrogen ions perform a function of controlling the PMA.

Spatially uniform control and an interface where two different regions are continuously well-connected are essential to realize the voltage-controlled skyrmion operation, and when a voltage is applied to the gated region of a skyrmion transistor according to an embodiment of the present invention configured in the structure as shown in FIG. 3, perpendicular magnetic anisotropy appears spatially uniform, and the gated region and non-gated region are continuously well-connected. This can be proved using Magneto-optical Kerr effect (MOKE) microscopy images.

As shown in FIG. 4, by using a MOKE microscope, the magnetic image of the CoFeB layer as shown in FIG. 5 can be obtained through the sufficiently thin Pt and W layers while simultaneously applying an electric voltage and a perpendicular magnetic field. The dark gray and light gray colors in FIG. 5 represent-z and +z magnetization domains of the MOKE image.

As shown in FIG. 3, a gate voltage is applied to the Pt top electrode, and the bottom electrode of the Ta/CoFeB/W layer is grounded. Accordingly, most of voltage drop occurs between the high-resistance TaOₓ/AlOₓ layers.

While a voltage is not applied, the magnetic channel exhibits a stripe domain pattern having a constant stripe domain width (2) as shown in FIG. 6(a).

The stripe domain width is exponentially proportional to domain wall energy.

Neel-type domain wall energy is given as

$$4 \sqrt{A {K}_{e f f}} - π D + \frac{ln 2}{π} {μ}_{0} {M}_{s}^{2} d ,$$

where A is the exchange stiffness,

$${K}_{eff} ( {K}_{eff} ( ≡ \frac{{μ}_{0} {M}_{s} {H}_{k}}{2} ) )$$

is the PMA energy density per volume, D is the Dzyaloshinski Moriya Interaction (DMI) energy density per area, and the last term is the volume demagnetization energy density.

Therefore, when the PMA is changed while A and D have the same value, a change occurs in the stripe domain width.

FIG. 6(a) shows that the entire region has the same PMA value. Then, after applying a gate voltage pulse of 4 V for 2 seconds in the left dashed line region (gated region), the stripe domain width is reduced only inside the gated region as shown in FIG. 6(b). When a gate voltage pulse is additionally injected, the stripe domain width is further reduced as shown in FIG. 6(c). The voltage-controlled stripe domain width remains even after the gate voltage is turned off and shows a non-volatile operation.

When a fast Fourier transform (FFT) is performed on the gated region and the non-gated region as shown in FIGS. 6A-6C, the images appear as shown in FIGS. 7(a) to (f). These FFT images clearly show that there is a change in the stripe domain width when a gate voltage is applied.

To clearly show that the PMA, not the DMI or other parameters, is manipulated when a gate voltage is applied, the Hₖ value in the gated region is measured after each gate voltage pulse is applied, using a MOKE microscope system. For reference, the change in the DMI due to the gate voltage is negligible.

$${m}_{z} = \frac{{H}_{z} + {m}_{z} {H}_{k}}{\sqrt{{( {H}_{z} + {m}_{z} {H}_{k} )}^{2} + {H}_{z}^{2}}}$$

In the above equation, m_{z} is normalized perpendicular magnetization corresponding to a normalized MOKE signal, and H_{z} is the perpendicular magnetic field. Hₖ is the effective PMA field, and Hₖ can be obtained using this equation.

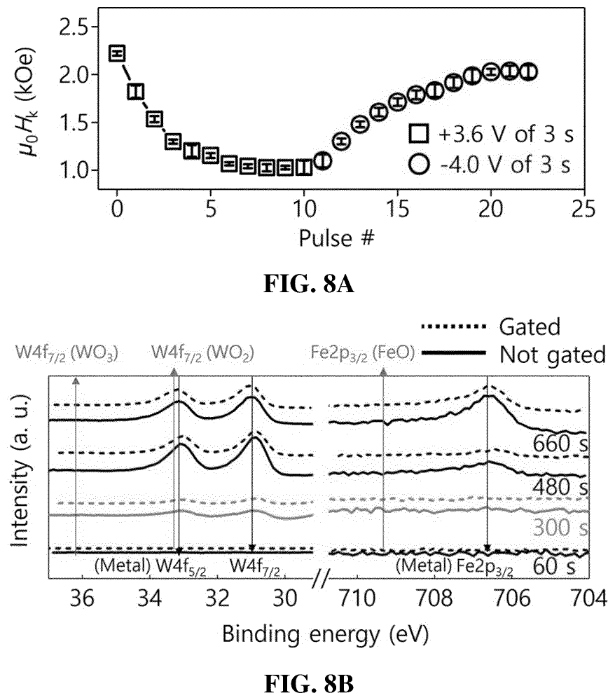

FIG. 8(a) shows the relationship between the gate voltage pulse and the perpendicular magnetic anisotropy field, and FIG. 8(b) shows the X-ray photoelectron spectroscopy analysis on the non-gate (solid line) and gate (dashed line) regions using in situ etching. In FIG. 8(a), the squares represent μ₀Hₖ after applying a positive gate voltage pulse, and the circles represent μ₀Hₖ after applying a negative gate voltage pulse.

When a gate voltage pulse of 3.6 V is applied for 3 seconds starting from the initial Hₖ of 2,221 Oe, Hₖ decreases (see FIG. 8(a)). When repeated gate pulses are used thereafter, the Hₖ value saturates at approximately 1,025 Oe as shown in the curve connected by the squares of FIG. 8(a).

A negative gate voltage pulse of −4.0V is sequentially applied for 3 seconds starting from the saturated Hₖ. Contrarily, the negative gate voltage pulse increases Hₖ, which eventually saturates to 2,037 Oe.

That is, it can be seen that the stripe domain width can be freely controlled by manipulating Hₖ according to the polarity or number of applied gate voltage pulses.

Researches on the voltage-controlled magnetic phenomena have utilized oxygen ion migration as an underlying mechanism. However, the experiment result obtained through an embodiment of the present invention cannot be explained by the oxygen ion migration mechanism.

In the thin film stack structure of the present invention as shown in FIG. 3, voltage drop mainly occurs between the TaOₓ/AlOₓ layers, and this shows that the electric fields exist only between oxide layers.

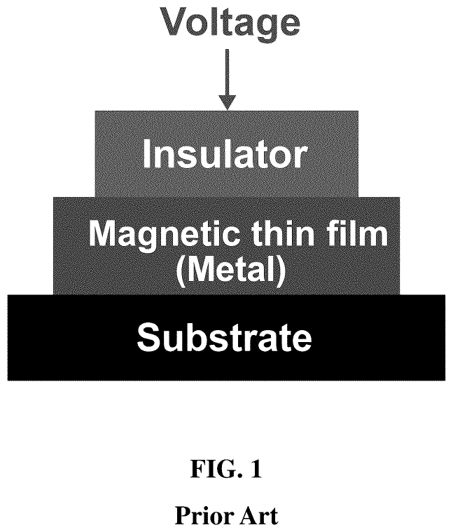

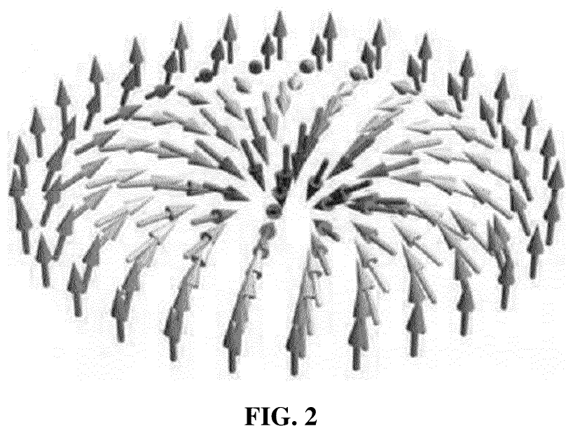

In the typical VCMA experiment using the concept of oxygen ion migration, a gate voltage is directly applied to the oxide layer in the layers of substrate/magnetic thin film/insulator (oxide layer) as shown in FIG. 1. However, in the thin film stack structure of the present invention (FIG. 3), the voltage is not directly applied to the oxide layer (MgO layer) in contact with the magnetic film (CoFeB), but the Ta/CoFeB/W layer is grounded, and the voltage is applied to the Pt electrode on the top of the TaOₓ/AlOₓ layers.

Accordingly, the positive gate voltage that reduces the PMA in the initial state attracts oxygen ions (O²⁻) at the W/TaOₓ interface. Therefore, unless the W layer initially has high resistance and abundant oxygen ions, the oxygen ion migration may not be the mechanism that explains the present invention.

To grasp the oxygen state inside the W layer in the gate/non-gated regions as shown in FIG. 8(b), X-ray photoelectron spectroscopy (XPS) analysis using in situ etching is performed.

Before putting a sample into the chamber, Hₖ of the gate/non-gated regions are measured to be 1,025 Oe and 2,221 Oe, respectively. In FIG. 8(b), the dashed curve represents the spectrum of the gated region, and the solid curve represents the spectrum of the non-gated region.

Each curve is applied with the etching time shown on the right side of FIG. 8(b).

Spin-orbit splitting of W4f core level for the W metal state is well observed at the binding energy positions of W4f (28 eV to 38 eV). The W metal peak begins to appear from the etching time of 300 seconds.

In addition, at the binding energy position of Fe2p_{3/2} (704 eV to 711 eV), a peak of Fe2p_{3/2} is observed for the Fe metallic state after an etching time of 480 seconds. The sufficient peak intensity of Fe2p_{3/2} during an etching time of 660 seconds indicates that the spectra during etching time of 660 seconds reflect the analysis near the CoFeB layer.

However, the oxide states of W and Fe are not observed in both the gated region and the non-gated region during all etching times. Therefore, as the underlying mechanism for VCMA in the present invention, oxygen ion migration may be excluded.

One of remaining possibilities is proton. Recently, various papers have reported magnetic property control through hydrogen adsorption. In addition, it has been proved recently that a proton pump operated by a gate voltage controls the magnetic anisotropy or ferrimagnetic ordering. It has been experimentally proved that a gate voltage may generate protons by dissociation of H₂O from the atmosphere on the surface and the protons may change the magnetic properties. The most feasible one that may output the result of the present invention would be the protons.

It may be said that ion migration is responsible for the non-volatile and reversible operation of VCMA by applying a gate voltage.

First, the most common oxygen ion may be considered, and as described above, oxygen migration may be excluded as the underlying mechanism.

The first reason is that there is no driving force that can move the oxygen ions previously existing in the two insulating layers (AlOₓ, TaOₓ) toward the ferromagnetic layer (CoFeB). As described above, the electric field existing only in the insulating layers cannot push the oxygen ions out of the insulating layers. The XPS analysis of FIG. 8(b) also does not show oxygen spectra before and after VCMA.

Next, boron ions in the CoFeB layer may be considered. When a post-annealing process is performed in the present invention to promote PMA, boron atoms in the CoFeB layer are diffused to the adjacent W layer owing to the large negative mixed enthalpy of W and B (ΔH_{W-B}=−31 KJ/mol). Therefore, the electric field may affect the boron ions near the interface between the TaOₓ and W layers.

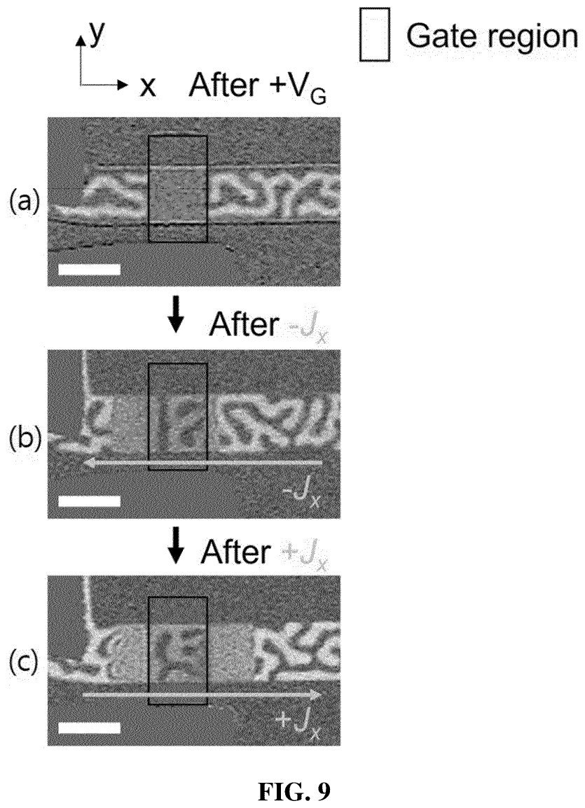

FIG. 9 is a view showing movement of the gated region by the strong transverse current injection. The present invention provides an indirect experiment evidence showing that boron is not related to the underlying mechanism. As shown in FIG. 9, a gate voltage sufficient to reduce the PMA in the gated region is injected. Therefore, the gray region in the gated region of FIG. 9(a) represents a stripe domain having a width smaller than the optical resolution or the in-plane magnetization state. After the gate voltage is cut off, a strong current (4.0 V) is applied along the −x-axis for 5 minutes (FIG. 9(b)). As shown in FIG. 9(b), as the strong and long in-plane current injection pushes the existing gray region to the left, the gated region is restored. Subsequently, a 4.0-V current is injected along the +x-axis for 5 minutes. In this case, as the current pushes the existing gray region to the right, the left region is slightly restored. However, when the gate control does operate, the transverse current injection does not change the magnetic anisotropy although the current amplitude is higher (10 V) and the injection time is longer (10 minutes). Changes in the magnetic anisotropy due to lateral current injection, except the Joule heating effect, have not been reported in the CoFeB-based structure. The operation direction in FIG. 9 shows that Joule heating is not the dominant mechanism. Accordingly, boron ions that already exist before the gate operation may not explain the result of the experiment described above. Therefore, it may be said that the underlying mechanism for VCMA in the present invention is due to hydrogen ion migration.

Spatially uniform control and an interface where two different regions are continuously well-connected are essential to realize the voltage-controlled skyrmion operation. However, VCMA based on oxygen ion migration shows spatially non-uniform behaviors or generation of defects due to the heavy and large properties of oxygen ions. For example, when a defect occurs during the VCMA operation, as the migrated skyrmions are trapped, further movement thereof may be restricted, or the skyrmions may be annihilated.

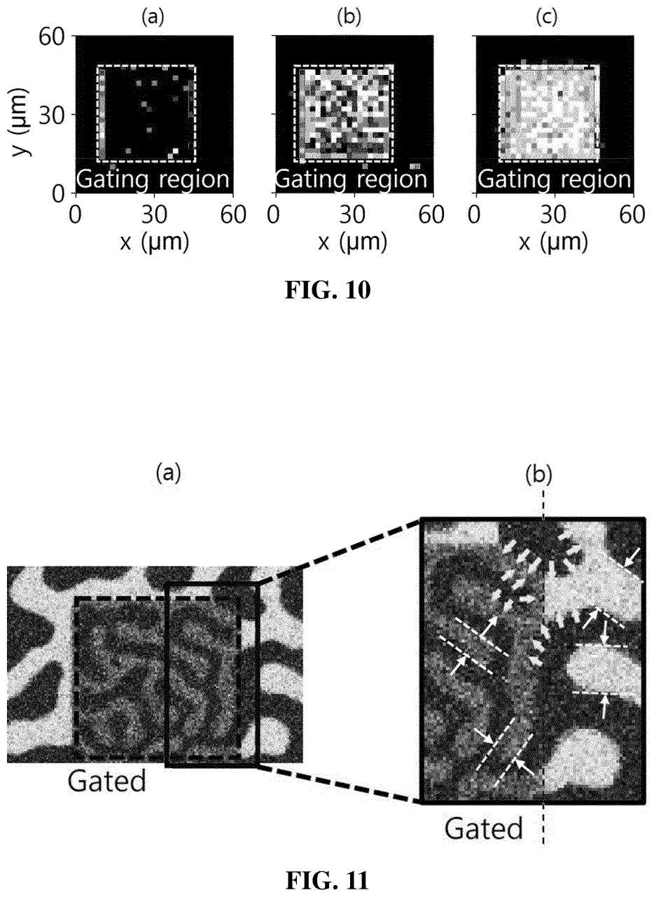

FIG. 10 is a view showing the results of investigating spatial uniformity of voltage-controlled perpendicular magnetic anisotropy. FIG. 10(a) shows mapping of an effective perpendicular magnetic anisotropy field in the initial state, FIGS. (b) and (c) show the mapping after applying a positive gate voltage pulse.

FIG. 11 is a view showing the results of investigating magnetic domain connection between a gated region and a non-gated region. FIG. 11 shows continuous deformation of the stripe domain through two different perpendicular magnetic anisotropy regions, and the bold arrows shown in FIG. 11(b) indicate the magnetization direction at the domain wall, which shows that chirality is well conserved.

As shown in FIG. 10, the spatial uniformity of the voltage-controlled stripe domain width is investigated by spatially mapping the Hₖ after each gate voltage pulse. The noise data at the edge of the gate is since 2×2 pixels of an original MOKE image are analyzed as one mapping data point on the x-y plane. In the initial state (FIG. 10(a)), the gating region (the white dashed box in FIG. 10(a)) has almost the same mapping color (Hₖ, average value of 2803 Oe) as the non-gating region.

After applying the first gate voltage pulse of 4 V for 3 seconds, Hₖ in the gating region is well controlled as shown in FIG. 10(b) (average value, 2234 Oe). The standard deviation of the inner gated region is 91 Oe. The second gate voltage pulse of 4 V applied for 3 seconds further reduces the Hₖ (the average value of Hₖ, 1749 Oe). Here, the standard deviation of the Hₖ is 67 Oe. Considering the error range of the method of measuring the Hₖ, the operation of the voltage-controlled stripe domain width is highly uniform inside the gated region.

In addition, in the present invention, magnetic domain connection between two different stripe domain width regions is investigated as shown in FIG. 11. The dashed box region is the voltage-controlled stripe domain width region, and the other region is the non-gated region. FIG. 11(b) is the enlarged image of the solid box shown in FIG. 11(a). The stripe domain width inside the non-gated region is almost twice that in the gated region. However, at the interface of the two regions (the dashed line in FIG. 11(a)), the two types of stripe domains having different stripe domain widths are well connected by the spatially continuous stripe domain deformation as shown in FIG. 11(b).

Due to the interfacial DMI from the W layer, the domain walls of the stripe domains in the two regions have the configuration of a Neel-type domain wall having left-handed chirality as indicated by the bold arrows in FIG. 11(b). It can be seen that the domain wall chirality, which determines the topological features, is well conserved through stripe domain width regions different from each other.

As the skyrmion generator of the skyrmion transistor according to an embodiment of the present invention having a structure as shown in FIG. 3 has a spatially uniform magnetic anisotropy and an interface where a gated region and a non-gated region are continuously well connected, skyrmions can be generated and stored quickly and stably.

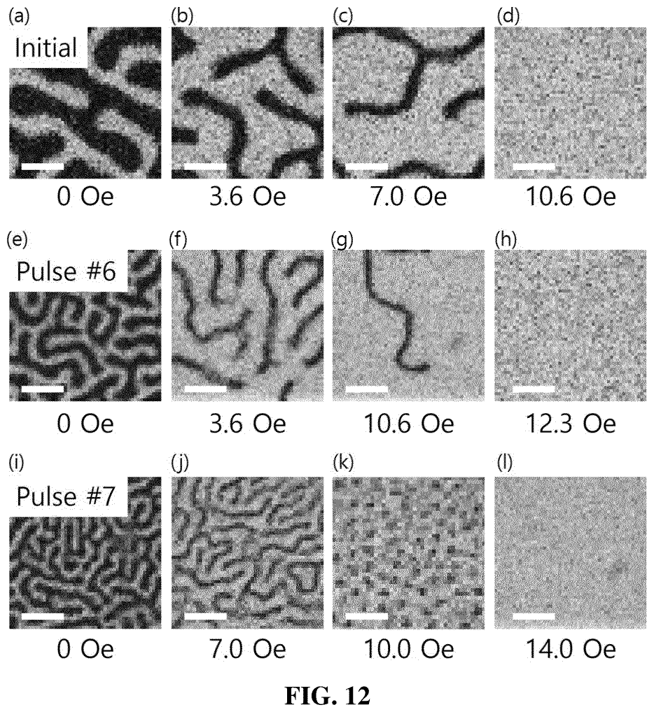

FIG. 12 is a view showing MOKE images of a stripe domain at various μ₀H_{Z} (Scale bar 5 μm). FIGS. 12(a) to (d) show MOKE images in the initial state, FIGS. 12(e) to (h) show MOKE images after the sixth gate voltage pulse, and FIGS. 12(i) to (l) show MOKE images after the seventh gate voltage pulse.

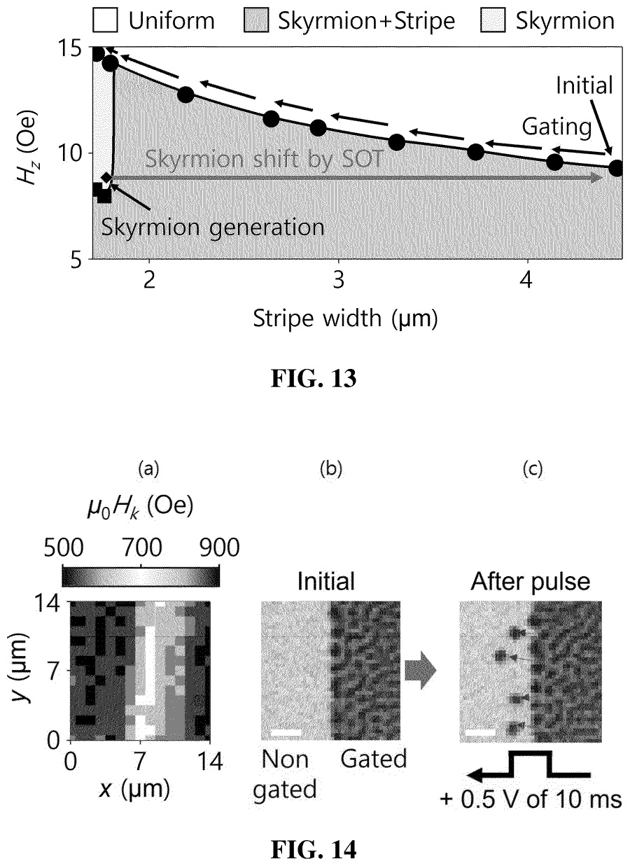

FIG. 13 is a view showing the phase diagram between the voltage-controlled stripe domain width and the stripe domain-skyrmion-uniform states under the z-axis magnetic field. The white, dark gray, and light gray regions represent the uniform state, skyrmion+stripe state, and skyrmion state, respectively.

FIG. 14(a) is a view showing mapping of an effective perpendicular magnetic anisotropy field, and FIGS. 14(b) and (c) show MOKE images in the initial state and after injection of in-plane current, respectively. In FIG. 14(a), the left region is the non-gated region and the right region is the gated region. FIG. 14(b) shows the MOKE image in the initial state, and FIG. 14(c) shows the MOKE image after injection of in-plane current pulse (Scale bar 3 μm).

Skyrmion properties including the skyrmion radius and skyrmion stability are determined by the stripe domain width in the zero magnetic field. In particular, the energy landscape of the stripe domain-skyrmion-uniform state under the z-axis magnetic field (H_{z}) is mainly a function of the stripe domain width regardless of other material parameters.

For example, the initial state has a stripe domain width of 4.58 μm at the zero magnetic field as shown in FIG. 12(a). When +H_{Z} is applied thereafter, the −z-axis stripe region is gradually reduced, and eventually a uniform magnetic state is formed at +H_{Z} of 10.6 Oe (FIGS. 12(a) to (d)).

When six positive gate voltage pulses of 3.6 V are injected for 3 seconds thereafter, the stripe domain width is reduced to 2.19 μm as shown in FIG. 12(e). When +H_{Z} is applied here, the same operation as the initial state is shown, but the +H_{Z} amplitude for reaching a uniform state slightly increases from 10.6 Oe to 12.8 Oe (FIGS. 12(d) and (h)).

When a positive gate voltage pulse of 3.6V is added for 3 seconds thereafter, the stripe domain width is reduced to 1.80 μm as shown in FIG. 12(i). When +H_{Z} of 10.0 Oe is applied as shown in FIG. 12(k), a skyrmion state is formed, and a uniform state is shown at +H_{Z} of 14.0 Oe.

When the thermal fluctuation at the two adjacent domain walls of the stripe domain is sufficient, phase transition from the stripe domain state to the skyrmion state may occur. Accordingly, in a specific stripe domain width or larger, the skyrmion state is not observed although the skyrmion state is a global minimum state (see FIG. 13).

In FIG. 13, the initial state (FIG. 12(a)) corresponds to the rightmost black circle in FIG. 13. When a positive gate voltage pulse is applied, the stripe domain width (arrows along the curve in FIG. 13) decreases, and +H_{Z} increases to reach a uniform state. As a result, under the stripe domain width of 1.80 μm, the skyrmion state can be observed only when H_{z} is applied. In FIG. 13, the skyrmion is in the global minimum state near the curve, and this may not be observed only by H_{z}.

According to the phase diagram like this, it can be seen that the skyrmions in the gate control region having a stripe domain width of 1.80 μm can be transferred to the non-gated region using the spin-orbit torque (SOT) (the long arrow pointing right at the center of FIG. 13).

To verify this, the stripe domain width of approximately 1.80 μm is voltage-controlled in each right region of FIGS. 14(a) to (c), and each left region of (a) to (c) is not gated. FIG. 14(a) shows Hₖ mapping data showing clearly different Hₖ in the two regions.

At +H_{Z} of 8.7 Oe, the non-gated region is in a skyrmion or skyrmion+stripe domain state. Although skyrmions are not generated spontaneously in this state as the thermal energy is insufficient, once generated, they are stable.

The gated region is in the skyrmion state under +H_{Z} of 8.7 Oe, and skyrmions are spontaneously generated owing to the sufficiently small stripe domain width as shown in FIG. 14(b). Here, when an in-plane current pulse of 0.5 V is injected for 10 ms, skyrmions in the gated region are pushed to the non-gated region by the SOT as shown in FIG. 14(c), and skyrmions are spontaneously generated and fill the empty space in the gated region. The skyrmions shifted from the gated region are stable even in the non-gated region at the +H_{Z} of 8.7 Oe.

Skyrmion migration from the gated region to the non-gated region is only possible when the shape and topology of the skyrmions are well conserved as they pass through the interface between the gate/non-gated regions. This operation shows that the present invention can be used as a new skyrmion generator, and since skyrmions are generated spontaneously, the gated region may be considered as a skyrmion reservoir.

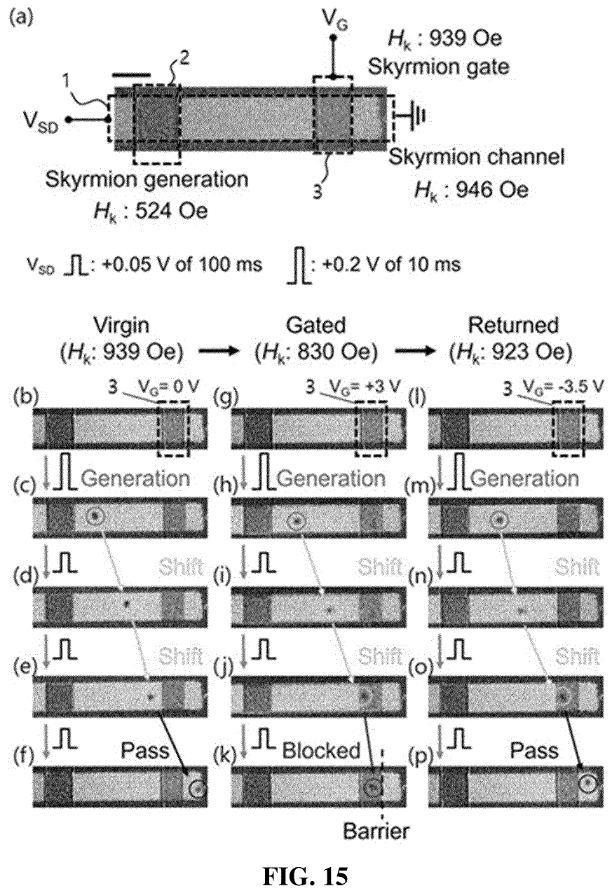

FIG. 15(a) is a view showing a skyrmion transistor according to an embodiment of the present invention, and FIGS. 15(b) to (p) are views showing the operation of the skyrmion transistor according to an embodiment of the present invention.

In FIG. 15(a), the horizontally long dashed box 1 is the skyrmion channel, the dashed box 2 on the left side functions as the skyrmion generator, and the dashed box 3 on the right side is the skyrmion gate (Scale bar, 10 μm). FIG. 15(b) shows the initial state, FIG. 15(c) shows the state in which a skyrmion is generated, and FIGS. 15(d) to (f) show skyrmions moving and passing through the skyrmion gate region.

FIGS. 15(g) to (k) show the operation after lowering the PMA of the skyrmion gate region by applying a positive gate voltage pulse, and FIG. 15(k) shows that the generated skyrmion is blocked at the right interface of the skyrmion gate region.

FIGS. 15(l) to (p) show the operation after the PMA is recovered in the skyrmion gate region by applying a negative gate voltage pulse, and FIG. 15(p) shows that the skyrmion may pass through the skyrmion gate region again.

As shown in FIG. 15, the present invention provides a new non-volatile skyrmion transistor by combining a new skyrmion generator and a precise voltage-controlled PMA operation. Hereinafter, a voltage-controlled skyrmion stabilization technique for application of a skyrmion logic device is experimentally shown.

A transistor is a semiconductor device used to switch electrical signals. In this sense, the skyrmion transistor of the present invention may function as a switch for skyrmion operation. When the gate voltage is turned off (or on), skyrmions may pass through, and when the gate voltage is turned on (or off), the skyrmions may be blocked.

In FIG. 15(a), the dashed box 1 represents a skyrmion channel with Hₖ of 946 Oe (non-gated region), and the dashed box 2 used as a skyrmion generator obtains Hₖ of 524 Oe by controlling the voltage. The dashed box 3 (skyrmion gate) is initially identical to the skyrmion channel as it is not gate-controlled.

When a V_{SD} pulse of 0.2 V is applied for 10 ms in the initial state, skyrmions inside the skyrmion generator are pushed into the skyrmion channel, and skyrmions are generated in the skyrmion channel as shown in FIG. 15(c). Thereafter, when the V_{SD} pulse is 100 ms, the skyrmions are pushed to the right side by the SOT, which does not generate additional skyrmions, as shown in FIGS. 15(d) and (e). In addition, as the skyrmion gate is identical to the skyrmion channel as shown in FIG. 15(f), skyrmions pass through the skyrmion gate.

Next, a positive gate voltage (V_{G}) of 3.0 V is applied for 3 seconds to reduce the Hₖ of the skyrmion gate to 830 Oe. Similarly, when the V_{SD} pulse is 10 ms, skyrmions are generated in the skyrmion channel (FIG. 15(h)), and when the V_{SD} pulse is 0.05 V for 100 ms, the skyrmions are shifted (FIGS. 15(i) and (j)). However, as shown in FIG. 15(k), skyrmions may not pass through the right interface of the skyrmion gate while passing through the left interface of the skyrmion gate.

In addition, when Hₖ of the skyrmion gate is returned to 923 Oe by applying a negative gate voltage (V_{G}) of −3.5 V for 3 seconds, skyrmions may pass through the skyrmion gate region again as shown in FIG. 15(p). The operations of FIGS. 15(b) to (p) represent the operation of the skyrmion transistor of the present invention.

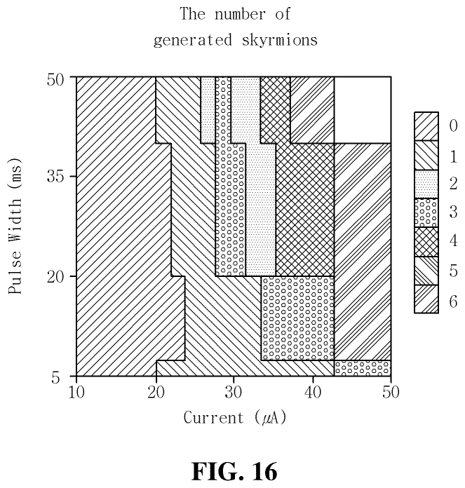

FIG. 16 is a view showing the number of skyrmions generated by a skyrmion generator according to the amplitude and time of injected current pulse. The number of magnetic skyrmions emitted from the skyrmion generator may be controlled by selecting the width (duration of the pulse) and amplitude (intensity of the pulse) of the injected current pulse as shown in FIG. 16. In addition, existing skyrmions may move within the zero skyrmion generation range of the red color.

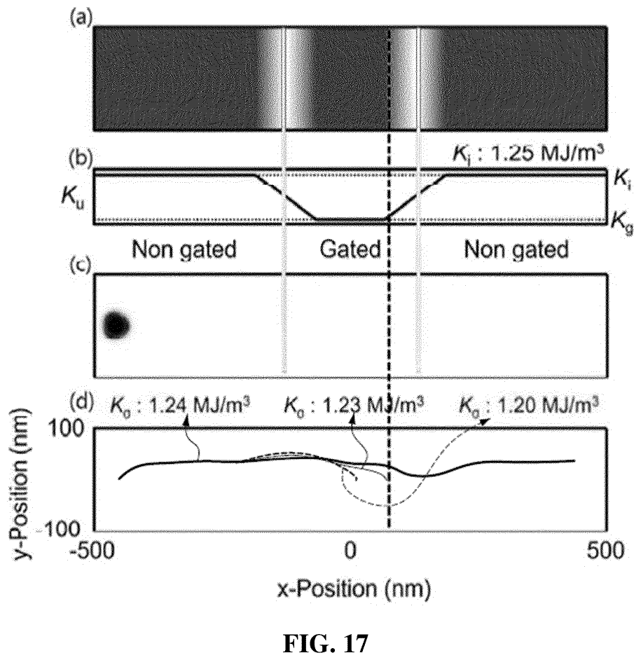

FIG. 17 is a view showing a micromagnetic simulation of a skyrmion transistor. A spin dynamics simulation is performed using MuMax3 software to explain the microscopic mechanism of the skyrmion transistor operation. FIG. 17(a) shows the spatial distribution of PMA energy density per volume, FIG. 17(b) shows its line profile (the central lower PMA region is the gated region), FIG. 17(c) shows the initial skyrmion position, and FIG. 17(d) shows skyrmion trajectories generated by SOTs having different PMA energy densities in the gated region.

The skyrmions are stabilized by selecting material parameters for the micromagnetic simulation of FIG. 17. Here, the saturation magnetization is 1,130 kA/m³, the exchange stiffness is 16 pJ/m³, the DMI energy density is-3 mJ/m², and the damping constant is 0.3. The PMA energy density in the non-gated region is 1.25 MJ/m³, and the PMA energy density in the gated region varies from 1.20 MJ/m³ to 1.24 MJ/m³. To move the skyrmions, a y-axis direction spin-polarized current with a current density of 9 A/m² is injected.

To schematically explain the skyrmion transistor of the present invention, spatial distribution of the PMA energy density is set as shown in FIG. 17(a), and a line profile of the K_{U} distribution is presented as shown in FIG. 17(b). The central lower K_{U} region is the gated region, and the other regions are non-gated regions.

The K_{U} of the non-gated region (Kᵢ) is set to 1.25 MJ/m³, and the K_{U} of the gated region (K_{g}) is a variable. Initially, skyrmions are arranged at the left far end (FIG. 17(c)), and the skyrmions are shifted with three different K_{g} values by injecting a y-axis direction spin-polarized current.

When K_{g} is smaller than 1.24 MJ/m³ as shown in FIG. 17(d), the skyrmions may not pass through the gated region, and the blocked point is the same as the starting point of the gradient region indicated by the vertical black dashed line shown in FIG. 17.

Considering the energy of the skyrmions, as the energy of the skyrmions is proportional to K_{U}, K_{U} may act as potential energy of the skyrmions. Accordingly, a force will act on the skyrmions, like a negative gradient potential energy that applies a force to classical particles. Therefore, the skyrmions may pass through the gate by a high driving current.

Hereinafter, various device performances of the skyrmion transistor of the present invention will be described.

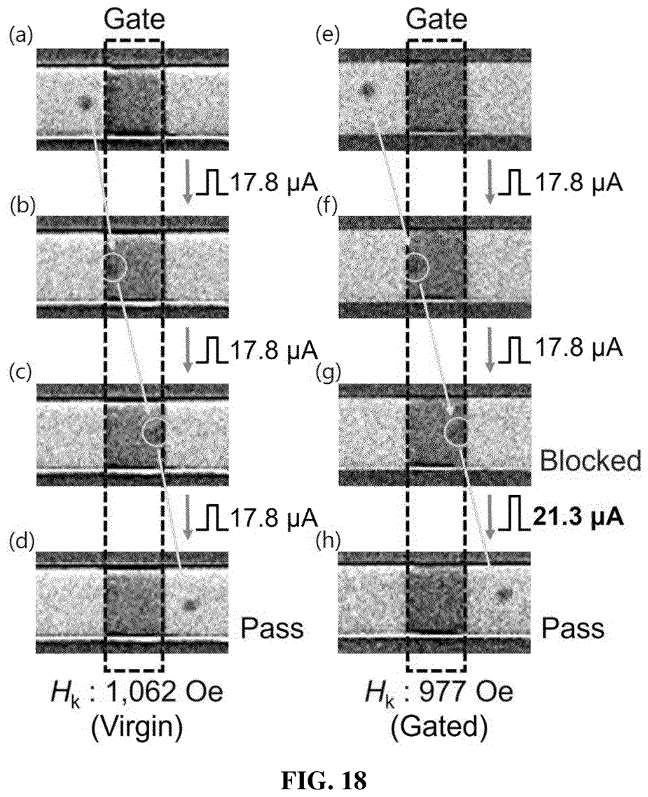

FIG. 18 is a view showing various operations of a skyrmion transistor. FIGS. 18(a) to (d) show the transitional motion of skyrmions passing through a gated region having an initial PMA (1,062 Oe) by a current pulse of 17.8 μA, FIGS. 18(e) to (g) show that a skyrmion driven by the current pulse of 17.8 μA is blocked at the right interface (977 Oe) of the gated region, and FIG. 18(h) shows that the higher the current pulse (21.3 μA), more skyrmions pass through the gated region.

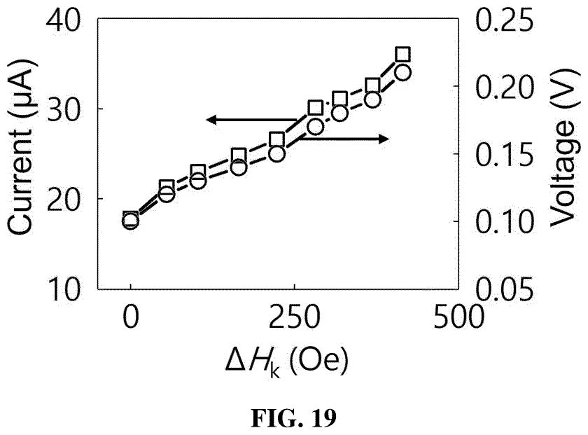

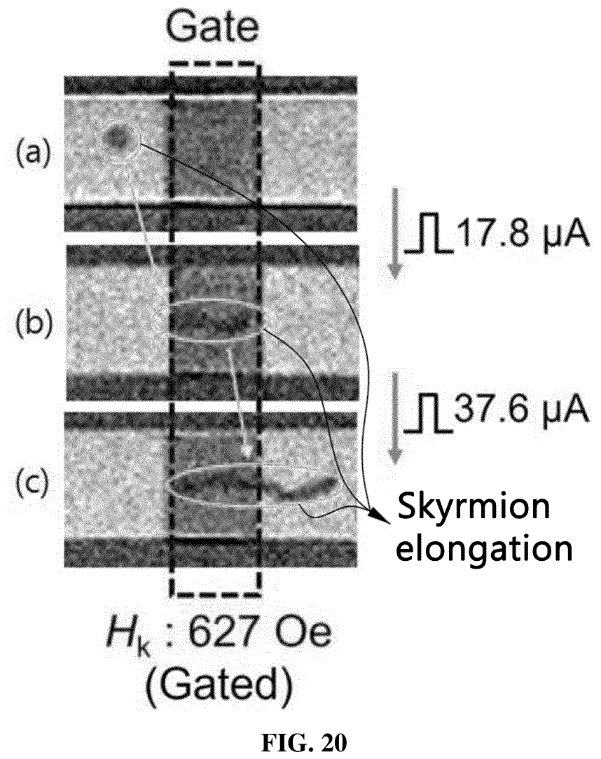

FIG. 19 is a view showing the threshold current of a skyrmion for overcoming the energy barrier of a gate as a function of Hₖ difference between a channel region and a gated region, and FIG. 20 is a view showing that a skyrmion transistor does not operate when the PMA of the gated region is smaller than the threshold value.

To confirm various performances of the skyrmion transistor of the present invention, skyrmion transistor operations are performed at various current densities.

As shown in FIGS. 18(a) to (d), since the gated region is the same as the channel region, skyrmions pass through the gated region with a current pulse of 17.8 μA of 30 ms. This means that skyrmions may pass through or be blocked by adjusting the in-plane current. Accordingly, the skyrmion transistor of the present invention may operate by controlling the in-plane current, as well as the gate voltage.

In addition, the Hₖ value of the gated region is lowered to 977 Oe by injecting a gate voltage. The difference in the Hₖ value between the gated region and the channel region generates an energy barrier for skyrmions, and blocks the translational motion of the skyrmions by the current pulse of 17.8 μA of 30 ms (FIG. 18(g)).

However, as shown in FIG. 18(h), a high current pulse (21.3 μA of 30 ms) induces a higher spin-orbit torque (SOT) and allows the skyrmions to pass through the gate. Since the PMA may act as the potential energy of the skyrmions, the height of the energy barrier varies according to the difference of the Hₖ value.

In the present invention, an experiment has been performed on the critical amplitude of a 30 ms current pulse to overcome the energy barrier as a function of difference of Hₖ value. The difference of Hₖ value (ΔHₖ) is defined by the equation shown below.

$$Δ {H}_{k} = {H}_{k}^{channel} - {H}_{k}^{gate}$$

The threshold current increases as ΔHₖ increases.

Since the potential energy is the local energy of skyrmions, which is a function of PMA, Hₖ determines the potential energy of skyrmions. For the skyrmions to move from a low Hₖ region to a high Hₖ region, ΔHₖ (i.e., the effective force due to the potential energy gradient) should be overcome.

In addition, when Hₖ of the gated region is controlled to an excessively small value (627 Oe as shown in FIGS. 20(a) to (c)), the skyrmion entering the gate is elongated as shown in FIG. 20(c). The magnitude of H_{z} required to reach the skyrmion state increases together with decrease of Hₖ.

At the threshold value H_{z} for the skyrmion state, the stripe domain is more stable than the skyrmion, and the skyrmion is elongated into the stripe domain in the gated region. Thereafter, when a sufficient current pulse is injected to push the elongated domain, the domain is further elongated, new skyrmions are not generated.

This means that there is Hₖ of a specific range in which the skyrmion transistor may operate, and this should be taken into account in designing devices based on the skyrmion transistor.

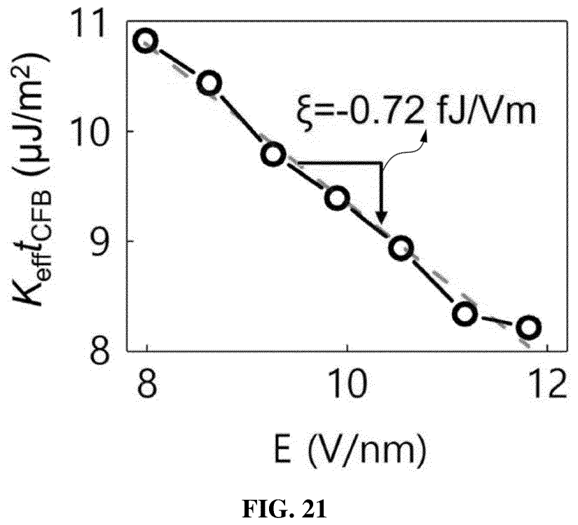

FIG. 21 is a graph showing VCMA efficiency with respect to the electric field. As shown in FIG. 21, VCMA efficiency is confirmed through an experiment. VCMA efficiency is obtained from the slope of the linear fitting line with respect to the graph shown in FIG. 21. The value of −0.72 fJ/Vm is lower than reported values. However, considering that the underlying mechanism of VCMA is a proton-mediated process, the efficiency calculated by the electric field should be considered carefully.

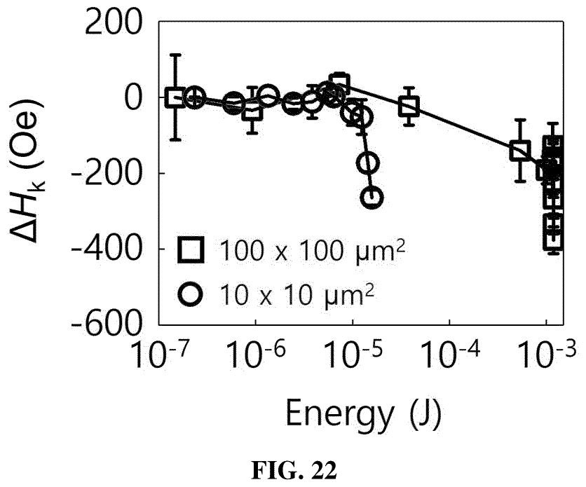

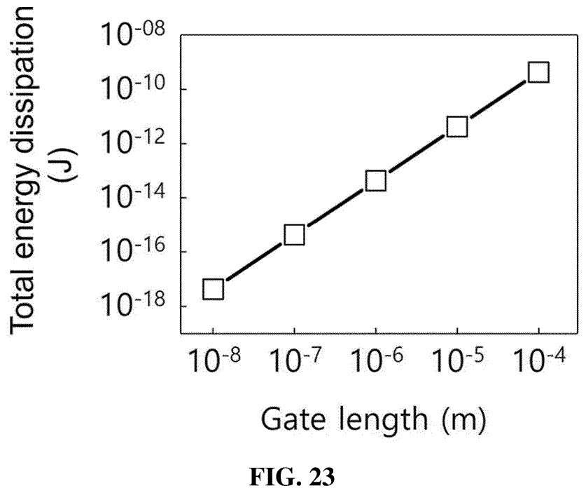

FIG. 22 is a graph showing energy consumption for VCMA operation, and FIG. 23 is a graph showing total energy dissipation with respect to the length of a gate.

In present invention, the total energy dissipation for one gate operation is calculated considering the maximum storage energy of the capacitor. The effective capacitance of the total TaOₓ(2 nm)/AlOₓ(2 nm) layer of 10×10 μm² may be calculated as 2.81×10⁻¹² F using the dielectric constants of 22 and 9 of TaOₓ and AlOₓ, respectively. Then, the energy stored during the 3-V gate operating in the insulating layer is 4.21×10⁻¹² J.

Here, the interfacial PMA energy density (J/m²), not the effective PMA energy density (J/m³), is controlled by the gate operation. This means that the charges required to induce the VCMA effect are proportional to the gating region. Therefore, the total energy dissipation decreases as much as the square of the gate length as shown in FIG. 23.

In addition, an experimental electrical energy for gating operation that manipulates the PMA is measured using E=Vit. Here, V is the voltage, I is the leakage current, and t is the duration time of the gating voltage pulse. FIG. 22 shows that the minimum electrical energy for manipulating Hₖ decreases as much as the square of the gate length. Therefore, when the gated region is 100 nm or less, the energy required for the operation is expected to decrease to the nJ scale.

Finally, the device of the present invention shows a leakage current within the range of μA, and this is a factor of increasing energy consumption. In the present invention, an experiment using a thin AlOₓ layer obtains clear MOKE images through the AlOₓ/Pt layers. Therefore, when the leakage current is minimized, energy consumption may be further reduced by optimizing the thickness or quality of the dielectric layer. It is noteworthy that since the proton-based VCMA is originated from an electrochemical reaction, not an electric field, the operating voltage is regardless of the thickness of the insulating layer.

As described above, the present invention proposes a voltage-controlled skyrmion stabilization technique accomplished by manipulating the PMA and stripe domain width. As the shape and topology of the skyrmions are well conserved as the skyrmions pass through the interface between the controlled/non-controlled regions, spatial uniformity of the voltage-controlled region may be appropriately applied to the skyrmion transistor of the present invention.

In addition, a new skyrmion generator having the concept of skyrmion reservoir may be provided using the voltage-controlled skyrmion stabilization technique presented in the present invention, and a new non-volatile skyrmion transistor may be provided by combining the concept of skyrmion generator with a precise voltage-controlled PMA.

The present invention will open a new way for designing and realizing skyrmion forming apparatuses including logic devices based on skyrmion transistors.

As described above, optimal embodiments have been disclosed in the drawings and specifications. Although specific terms are used herein, they are used only to describe the present invention and are not intended to limit the scope of the present invention as described in the claims. Therefore, those skilled in the art will understand that various modifications and equivalent other embodiments are possible therefrom. Accordingly, the true scope of technical protection of the present invention should be determined by the technical spirit of the appended claims.

1. A skyrmion transistor comprising:
a substrate;
a skyrmion channel configured of a first thin film stack formed on the substrate to include a magnesium oxide (MgO) layer, a cobalt iron boron (CoFeB) layer, and a heavy metal layer, one side of which is grounded; and
a skyrmion generator and a skyrmion gate configured of the first thin film stack and a second thin film stack formed in a predetermined upper region thereof to include an aluminum oxide (AlOₓ) layer and an electrode layer.

2. The skyrmion transistor according to claim 1, wherein the skyrmion gate may pass or block skyrmions by adjusting a gate voltage.

3. The skyrmion transistor according to claim 2, wherein a perpendicular magnetic anisotropy of the gated region is adjusted by applying the gate voltage to control an energy barrier through which the skyrmions may pass.

4. The skyrmion transistor according to claim 3, wherein there is a threshold value of the perpendicular magnetic anisotropy of the gated region, at which the skyrmion transistor may operate.

5. The skyrmion transistor according to claim 1, wherein the skyrmion gate may pass or block skyrmions by adjusting in-plane current.

6. The skyrmion transistor according to claim 1, wherein the skyrmion generator controls the perpendicular magnetic anisotropy of a skyrmion generator region by applying a voltage to the skyrmion generator region through the electrode layer, and forms a skyrmion generating state in the skyrmion generator region and a skyrmion stable state in a skyrmion channel region by adjusting perpendicular magnetic fields of the skyrmion generator region and the skyrmion channel region, and discharges skyrmions from the skyrmion generator region to the skyrmion channel region by applying an in-plane current.

7. The skyrmion transistor according to claim 1, wherein when a voltage is applied to a gated region, perpendicular magnetic anisotropy appears spatially uniform in the gated region.

8. The skyrmion transistor according to claim 1, wherein the aluminum oxide layer is formed by atomic layer deposition (ALD) using an aluminum precursor and water at a relatively low temperature within a temperature range capable of deposition.

9. The skyrmion transistor according to claim 8, wherein the aluminum oxide layer contains hydrogen.

10. The skyrmion transistor according to claim 1, wherein the heavy metal layer is configured of at least one among W, Ta, Nb, and Hf.

11. The skyrmion transistor according to claim 1, wherein an ultra-thin metal layer is interposed between the cobalt iron boron layer and the magnesium oxide layer.

12. The skyrmion transistor according to claim 1, wherein a natural oxide layer or a metal oxide layer is formed on the top of the heavy metal layer.

13. The skyrmion transistor according to claim 1, wherein a magnetic image observed in the gated region using a Magneto-optical Kerr effect (MOKE) microscope shows a uniform stripe domain width.

14. The skyrmion transistor according to claim 1, wherein magnetization domains are spatially and continuously connected at an interface between the gated region and the non-gated region having different perpendicular magnetic anisotropy.

15. The skyrmion transistor according to claim 1, wherein domain wall chirality is well conserved at an interface between the gated region and the non-gated region having different perpendicular magnetic anisotropy.

16. The skyrmion transistor according to claim 1, wherein an in-plane current is a pulse current, and the number of generated skyrmions may be adjusted by controlling an amplitude and time thereof.
